(19) United States
(12) Patent Application Publication
(10) Pub. No.: US 2025/0379558 A1
(43) Pub. Date: Dec. 11, 2025

(54) INTERDIGITAL TRANSDUCER CAPACITOR WITH MODULATED PITCH

(71) Applicant: Skyworks Solutions, Inc., Irvine, CA (US)

(72) Inventors: Yiliu Wang, Irvine, CA (US); Rei Goto, Osaka-Shi (JP); Mitsuhiro Habuta, Osaka-Shi (JP)

(21) Appl. No.: 19/229,344

(22) Filed: Jun. 5, 2025

Related U.S. Application Data
(60) Provisional application No. 63/657,071, filed on Jun. 6, 2024.
(60) Provisional application No. 63/657,075, filed on Jun. 6, 2024.

(51) Int. Cl. H03H 9/64; H03H 9/05; H03H 9/145; H03H 9/25

(52) U.S. Cl. CPC H03H 9/6433; H03H 9/0542; H03H 9/14552; H03H 9/25

(57) ABSTRACT

Aspects of this disclosure relate to an interdigital transducer capacitor that includes capacitor fingers with different pitches between pairs of adjacent capacitor fingers. In certain embodiments, the interdigital transducer capacitor and an acoustic wave resonator can be formed of different regions of a piezoelectric layer. Related acoustic wave devices, filters, multiplexers, radio frequency modules, radio frequency systems, wireless communication devices, and methods are disclosed.

### CROSS REFERENCE TO PRIORITY APPLICATIONS

Any and all applications for which a foreign or domestic priority claim is identified in the Application Data Sheet as filed with the present application are hereby incorporated by reference under 37 C.F.R. § 1.57. This application claims the benefit of priority of U.S. Provisional Application No. 63/657,071, filed Jun. 6, 2024 and titled “INTERDIGITAL TRANSDUCER CAPACITOR WITH MODULATED PITCH,” and claims the benefit of priority of U.S. Provisional Application No. 63/657,075, filed Jun. 6, 2024 and titled “ACOUSTIC WAVE DEVICE INCLUDING RESONATOR AND CAPACITOR,” the disclosures of each of which are hereby incorporated by reference in their entireties and for all purposes.

### BACKGROUND

### Technical Field

Embodiments of this disclosure relate to interdigital transducer (IDT) capacitors. Some embodiments related to acoustic wave devices including an acoustic wave resonator and a capacitor.

### Description of Related Technology

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A SAW resonator can include an interdigital transductor electrode on a piezoelectric substrate. The SAW resonator can generate a surface acoustic wave on a surface of the piezoelectric layer on which the interdigital transductor electrode is disposed.

There are technical challenges related to meeting certain filter specifications with acoustic wave filters. For example, filters with steep skirts and relatively low insertion loss near band edges are typically desirable. Meeting certain filter specifications related to skirt steepness and/or low insertion loss while also meeting other filter specifications can be challenging.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

One aspect of this disclosure is an acoustic wave device that includes a piezoelectric layer having a first region and a second region, an interdigital transducer capacitor in the first region, and an acoustic wave resonator in the second region. The interdigital transducer capacitor including capacitor fingers including a first pair of adjacent capacitor fingers extending from a bus bar with a first pitch and a second pair of adjacent capacitor fingers extending from the bus bar with a second pitch different from the first pitch. The acoustic wave resonator includes an interdigital transducer electrode in communication with the piezoelectric layer. The interdigital transducer electrode includes resonator fingers having a pair of adjacent resonator fingers with a third pitch, the third pitch being different from both the first pitch and the second pitch.

The third pitch can be greater than both the first pitch and the second pitch.

A number of the resonator fingers can be greater than a number of the capacitor fingers.

The second pitch can be at least 3% greater than the first pitch. The second pitch can be less than 15% greater than the first pitch. The second pitch can be at least 5% greater than the first pitch. The second pitch can be at least 0.1 micrometer greater than the first pitch.

An area of the acoustic wave resonator can be greater than an area of the interdigital transducer capacitor. The acoustic wave resonator can be longer than the interdigital transducer capacitor along a wave propagation direction of the acoustic wave resonator.

The interdigital transducer capacitor can be free from an acoustic reflector.

Pitches of the capacitor fingers can have a gradient. Pitches of the capacitor fingers can be random or pseudo-random.

The interdigital transducer capacitor can generate substantially no aggregate resonance.

The interdigital transducer capacitor can be positioned along a wave propagation direction of the acoustic wave resonator.

The acoustic wave device can include a high viscosity material. The capacitor fingers can be positioned between the high viscosity material and the piezoelectric layer. The high viscosity material can have a higher viscosity than the piezoelectric layer.

The acoustic wave device can include a support substrate, where the piezoelectric layer is positioned between the support substrate and the interdigital transducer electrode.

The acoustic wave device can include a support substrate and an intermediate layer positioned between the support substrate and the piezoelectric layer.

The interdigital transducer capacitor can be in parallel with the acoustic wave resonator.

Another aspect of this disclosure is an interdigital transducer capacitor that includes a piezoelectric layer and an interdigital transducer including a bus bar and capacitor fingers on the piezoelectric layer. The capacitor fingers includes a first pair of adjacent capacitor fingers extending from the bus bar with a first pitch and a second pair of adjacent capacitor fingers extending from the bus bar with a second pitch different from the first pitch.

Pitches of the capacitor fingers can be modulated such that the interdigital transducer capacitor generates substantially no resonance.

Another aspect of this disclosure is an acoustic wave filter for filtering a radio frequency signal. The acoustic wave filter includes an interdigital transducer capacitor, an acoustic wave resonator in parallel with the interdigital transducer capacitor, and a plurality of additional acoustic wave resonators. The interdigital transducer capacitor includes capacitor fingers on a piezoelectric layer. The capacitor fingers include a first pair of adjacent capacitor fingers extending from a bus bar with a first pitch and a second pair of adjacent capacitor fingers extending from the bus bar with a second pitch different from the first pitch. The acoustic wave resonator includes an interdigital transducer electrode in communication with the piezoelectric layer. The interdigital transducer electrode includes resonator fingers having a pair of adjacent resonator fingers with a third pitch. The third pitch is different from both the first pitch and the second pitch. The acoustic wave resonator and the plurality of additional acoustic wave resonators are configured to filter the radio frequency signal.

The acoustic wave filter can include a second interdigital transducer capacitor in parallel with a second acoustic wave resonator of the plurality of additional acoustic wave resonators.

Another aspect of this disclosure is an acoustic wave device that includes a capacitor and an acoustic wave resonator. The capacitor includes a first portion of piezoelectric layer and capacitor fingers. The capacitor is an interdigital transducer capacitor. The capacitor fingers include a first pair of adjacent capacitor fingers having a resonance at a first frequency and a second pair of adjacent capacitor fingers having a resonance at a second frequency different from the first frequency. The acoustic wave resonator includes a second portion of the piezoelectric layer and an interdigital transducer electrode on the piezoelectric layer. The interdigital transducer electrode includes resonator fingers. The capacitor is electrically coupled with the resonator in parallel.

Dimensions of the first pair of adjacent capacitor fingers and dimensions of the second pair of adjacent capacitor fingers can be different.

A number of the resonator fingers can be greater than a number of the capacitor fingers.

The resonator fingers can have a pair of adjacent resonator fingers configured to generate a third frequency. The third frequency can be higher than both the first frequency and the second frequency.

The acoustic wave resonator can include a pair of acoustic reflectors. The interdigital transducer electrode can be positioned between the pair of acoustic reflectors.

The second frequency can be at least 3% greater than the first frequency. The second frequency can be less than 15% greater than the first frequency. The second frequency can be at least 5% greater than the first frequency.

An area of the acoustic wave resonator can be greater than an area of the capacitor.

The capacitor can be free from acoustic reflectors.

Pitches of the capacitor fingers can have a gradient pitch profile. Pitches of the capacitor fingers can have a random or pseudo-random pitch profile.

The capacitor can generate substantially no aggregate resonance.

The capacitor can be positioned along a wave propagation direction of the acoustic wave resonator.

The acoustic wave device can include a multilayer piezoelectric substrate. The acoustic wave device can include a support substrate and an intermediate layer positioned between the support substrate and the piezoelectric layer.

Another aspect of this disclosure is an acoustic wave filter for filtering a radio frequency signal. The acoustic wave filter includes an interdigital transducer capacitor and an acoustic wave resonator in accordance with any suitable principles and advantages disclosed herein and a plurality of additional acoustic wave resonators. The acoustic wave resonator and the plurality of additional acoustic wave resonators are configured to filter the radio frequency signal.

Another aspect of this disclosure is a multiplexer for filtering radio frequency signals. The multiplexer includes a first filter including an interdigital transducer capacitor and an acoustic wave resonator in accordance with any suitable principles and advantages disclosed herein, and a second filter coupled to the first filter at a common node.

Another aspect of this disclosure is a radio frequency module that includes a filter including an interdigital transducer capacitor and an acoustic wave resonator in accordance with any suitable principles and advantages disclosed herein, radio frequency circuitry, and a package structure enclosing the filter and the radio frequency circuitry.

Another aspect of this disclosure is a radio frequency system that includes an antenna, a filter including an interdigital transducer capacitor and an acoustic wave resonator in accordance with any suitable principles and advantages disclosed herein, and an antenna switch configured to selectively electrically connect the antenna and a signal path that includes the filter.

Another aspect of this disclosure is a wireless communication device that includes a radio frequency front end including a filter that includes an interdigital transducer capacitor and an acoustic wave resonator in accordance with any suitable principles and advantages disclosed herein, an antenna coupled to the radio frequency front end, a transceiver in communication with the radio frequency front end, and a baseband system in communication with the transceiver.

Another aspect of this disclosure is a method of radio frequency signal processing. The method includes receiving a radio frequency signal via at least an antenna; and filtering the radio frequency signal with a filter that includes an interdigital transducer capacitor and an acoustic wave resonator in accordance with any suitable principles and advantages disclosed herein.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

### BRIEF DESCRIPTION OF THE DRAWINGS

Embodiments of this disclosure will now be described, by way of non-limiting example, with reference to the accompanying drawings.

FIG. 1A is a schematic top plan view of an interdigital transducer (IDT) capacitor according to an embodiment.

FIG. 1B is a schematic cross-sectional side view of the IDT capacitor of FIG. 1A.

FIG. 2A is a schematic top plan view of a surface acoustic wave (SAW) device that includes the IDT capacitor of FIG. 1A and a SAW resonator.

FIG. 2B is a schematic cross-sectional side view of the SAW device of FIG. 2A.

FIG. 3 is a schematic top plan view of an example layout of a filter that includes the SAW device of FIG. 2A.

FIG. 4 is a graph showing simulated frequency responses of a filter without an IDT capacitor and a filter with an IDT capacitor having capacitor fingers having a constant pitch.

FIG. 5A is a graph showing an example profile of the capacitor fingers having a constant pitch.

FIG. 5B is a graph showing an example profile of the capacitor fingers having a gradation pitch.

FIG. 5C is a graph showing simulated frequency responses of the IDT capacitors having the capacitor finger profiles of FIGS. 5A and 5B.

FIG. 5D is an enlarged view of a portion of the graph of FIG. 5C.

FIGS. 6A, 6B, 6C, 6D, 6E, 6F, 6G, 6H, and 6I are graphs showing simulated filter response results of different filters.

FIGS. 7A and 7B are graphs showing evaluation board measurement results of different filters.

FIGS. 8A, 8B, 8C, and 8D are graphs showing simulated frequency responses results of different resonators.

FIG. 9A is a schematic top plan view of a SAW device that includes an IDT capacitor according to an embodiment.

FIG. 9B is a schematic cross-sectional side view of the SAW device of FIG. 9A.

FIGS. 9C, 9D, 9E, 9F, 9G, and 9H are schematic cross-sectional side views of SAW devices according to various embodiments.

FIG. 10A is a schematic diagram of an example filter that includes surface acoustic wave devices according to an embodiment.

FIG. 10B is a schematic diagram of another filter that includes surface acoustic wave devices according to an embodiment.

FIG. 11 is a schematic diagram of a radio frequency module that includes a surface acoustic wave resonator and an IDT capacitor according to an embodiment.

FIG. 12 is a schematic diagram of a radio frequency module that includes filters with an acoustic wave resonator and an IDT capacitor according to an embodiment.

FIG. 13 is a schematic block diagram of a module that includes an antenna switch and duplexers that include an acoustic wave resonator and an IDT capacitor according to an embodiment.

FIG. 14A is a schematic block diagram of a module that includes a power amplifier, a radio frequency switch, and duplexers that include an acoustic wave resonator and an IDT capacitor according to an embodiment.

FIG. 14B is a schematic block diagram of a module that includes filters, a radio frequency switch, and a low noise amplifier according to an embodiment.

FIG. 15A is a schematic block diagram of a wireless communication device that includes a filter with an acoustic wave resonator and an IDT capacitor in accordance with one or more embodiments.

FIG. 15B is a schematic block diagram of another wireless communication device that includes a filter with an acoustic wave resonator and an IDT capacitor in accordance with one or more embodiments.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. Certain SAW devices may be referred to as SAW resonators. Any features of the SAW resonators discussed herein can be implemented in any suitable SAW device, such as a multilayer piezoelectric substrate (MPS) SAW device. A bandwidth of a filter is defined as the range of frequencies over which the device can effectively filter signals. A larger effective electromechanical coupling coefficient or coupling factor (kt²) can contribute to providing a wider bandwidth for a SAW device. However, when a relatively large kt² SAW resonator is used in a filter, the skirt performance and the insertion loss of the filter can be degraded.

A capacitor can provide additional capacitance in parallel or in series with a SAW resonator of a filter. Capacitors can be used for various purposes in filters and/or other electronic circuits, such as tuning the resonant frequency or providing impedance matching. The capacitors can be coupled with SAW resonators to achieve desired electrical characteristics. For example, a capacitor in parallel with a SAW resonator of a filter can shift (increase or decrease) the coupling factor (kt²) and improve the skirt performance and the insertion loss of the filter. In some applications, such a capacitor is provided separately from the SAW resonator. The separately provided capacitor can introduce, for example, losses in the filter.

An interdigital transducer capacitor can enable integration of the capacitor with an acoustic wave resonator on a common piezoelectric layer. Such integration can lower losses in the filter. However, it can be challenging to provide the interdigital transducer (IDT) capacitor that generates relatively low or no resonance and has a relatively low quality factor (Q) at a resonant frequency (Fs). IDT capacitors that include capacitor fingers of the same pitch can form a resonance. In filter and/or multiplexer implementations, a high Q resonance mode in a rejection frequency range can be undesirable.

Aspects of this disclosure relate to IDT capacitors that include capacitor fingers with non-uniform pitches. Capacitor finger pitches can be dithered or otherwise modulated so that little or no resonance is formed. Such IDT capacitors can be used in a variety of filters, such as band pass filters where dithering or otherwise modulating pitch can reduce or eliminate resonance either above or below a filter passband. In some embodiments, a material with high viscosity can be included in an IDT capacitor region so that mechanical resonance Q is significantly dampened and the IDT capacitor still functions. For instance, a relatively soft damping material can be formed on the IDT capacitor to de-Q the main mode.

Embodiments disclosed herein relate to SAW devices that include an IDT capacitor. Such SAW devices can be referred to as capacitor integrated SAW resonators. A temperature compensated surface acoustic wave (TC-SAW) device, a non-temperature compensated surface acoustic wave device, a multi-layer piezoelectric substrate surface acoustic wave (MPS-SAW) device, and a multimode surface acoustic wave filter, such as a double mode surface acoustic wave filter, are examples of a SAW device. MPS SAW resonators have relatively high Q and accordingly can achieve significant benefits from being connected with IDT capacitors disclosed herein.

A SAW device can include a piezoelectric layer having a capacitor region (e.g., a first region) and a resonator region (e.g., a second region). A capacitor can be positioned in the capacitor region and a resonator can be positioned in the resonator region. The capacitor can include capacitor fingers having a first pair of adjacent capacitor fingers that extend from a same bus bar and a second pair of adjacent capacitor fingers that extend from the same bus bar. The first pair of adjacent capacitor fingers and the second pair of adjacent capacitor fingers can have different profiles such that a resonance generated by the first pair of adjacent capacitor fingers and a frequency of the second pair of adjacent capacitor fingers are at different frequencies. For example, the first pair of adjacent capacitor fingers can have a first pitch and the second pair of adjacent capacitor fingers can have a second pitch different from the first pitch. The difference(s) in the capacitor finger profile between the first and second pairs of adjacent capacitor fingers can enable the capacitor to generate little or no aggregate resonance. The resonator can include an interdigital transducer electrode in electrical communication with the piezoelectric layer. The interdigital transducer electrode can include resonator fingers. In some embodiments, the resonator fingers include a pair of adjacent resonator fingers with a third pitch. The third pitch can be greater than both the first pitch and the second pitch.

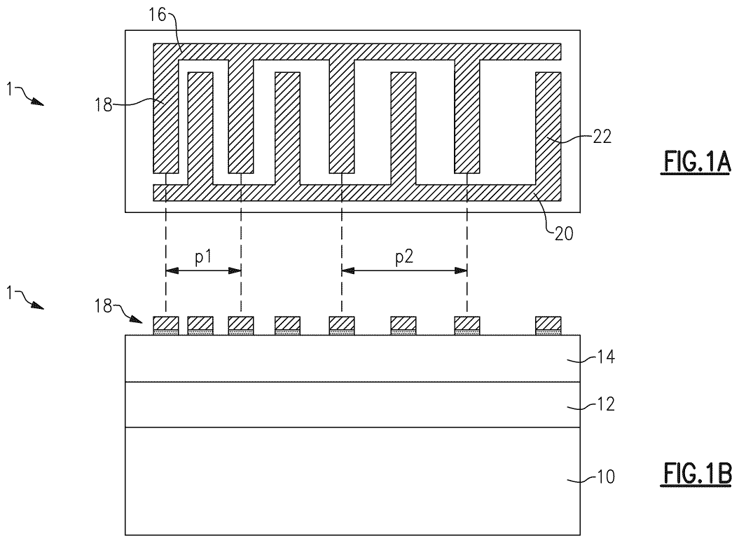

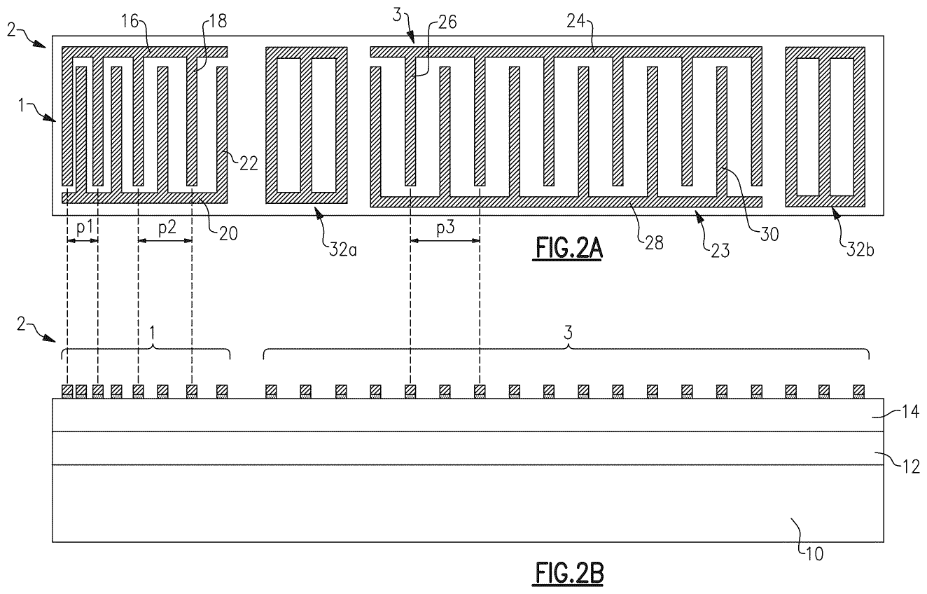

FIG. 1A is a schematic top plan view of an IDT capacitor 1 according to an embodiment. FIG. 1B is a schematic cross-sectional side view of the IDT capacitor 1. FIG. 2A is a schematic top plan view of a surface acoustic wave (SAW) device 2 that includes the IDT capacitor 1 and a resonator 3. FIG. 2B is a schematic cross-sectional side view of the SAW device 2. The SAW device 2 can be an MPS-SAW device, for example, as illustrated in FIGS. 2A and 2B.

The SAW device 2 can include a support substrate 10, an intermediate layer 12 over the support substrate 10, and a piezoelectric layer 14 over the intermediate layer 12. The piezoelectric layer 14 has a capacitor region corresponding to the IDT capacitor 1 and a resonator region corresponding to the resonator 3. In the SAW device 2, the resonator 3 is a SAW resonator. The IDT capacitor 1 can include a bus bar 16, capacitor fingers 18 that extend from the bus bar 16, a bus bar 20, and capacitor fingers 22 that extend from the bus bar 20. The resonator 3 can include an IDT electrode 23 that includes a bus bar 24, resonator fingers 26 that extend from the bus bar 24, a bus bar 28, and resonator fingers 30 that extend from the bus bar 28, and a pair of acoustic reflectors 32a, 32b. The IDT electrode 23 is in communication with the piezoelectric layer 14. The support substrate 10, the intermediate layer 12, and the piezoelectric layer 14 can together define an MPS.

The capacitor fingers 18 of the IDT capacitor 1 have a first pair of adjacent capacitor fingers 18 extending from the bus bar 16 with a first pitch p1 and a second pair of adjacent capacitor fingers 18 extending from the bus bar 16 with a second pitch p2 different from the first pitch p1. The second pitch p2 can be, for example, at least 3%, at least 5%, or at least 8% greater than the first pitch p1. The second pitch p2 can be, for example, less than 10%, less than 15%, less than 20% greater than the first pitch p1. The second pitch p2 can be, for example, at least 0.1 micrometer greater, at least 0.2 micrometers greater, or at least 0.3 micrometers greater than the first pitch p1.

A pitch p3 of adjacent resonator fingers 26 of the IDT electrode 23 can be different from both the first pitch p1 and the second pitch p2 of the IDT capacitor 1. Most or all of the pitches of adjacent capacitor fingers 18, 22 of the IDT capacitor 1 can be smaller than the pitch p3 of the resonator fingers 26 of the IDT electrode 23. The smaller pitch can produce a larger capacitance density in the capacitor 1. In some other embodiments, most or all of the pitches of adjacent capacitor fingers 18, 22 of the capacitor 1 can be greater than a pitch p3 of the resonator fingers 26 of the IDT electrode 23. There are fewer capacitor fingers of the capacitor 1 than resonator fingers of the IDT electrode 23. Although not shown in FIG. 2A, the capacitor 1 can have a smaller aperture than the resonator 3.

Although two pairs of adjacent capacitor fingers described for illustrative purposes, some or all pitches of the capacitor fingers 18 may have different pitches. The capacitor fingers 22 can have the same or similar profile as the capacitor fingers 18. A pitch of fingers sets the wavelength 2 or L of an acoustic wave that the fingers can generate. Because the first pitch p1 and the second pitch p2 are different, the first pair of adjacent capacitor fingers and the second pair of adjacent capacitor fingers generate acoustic waves of different frequencies. Accordingly, the IDT capacitor 1 can generate little or no aggregate resonance. The IDT capacitor 1 can be integrated with the resonator 3 with relatively small or no interference with the performance of the resonator 3. As illustrated, unlike the resonator 3, the IDT capacitor 1 does not include an acoustic reflector. However, in some applications, the IDT capacitor may include an acoustic reflector.

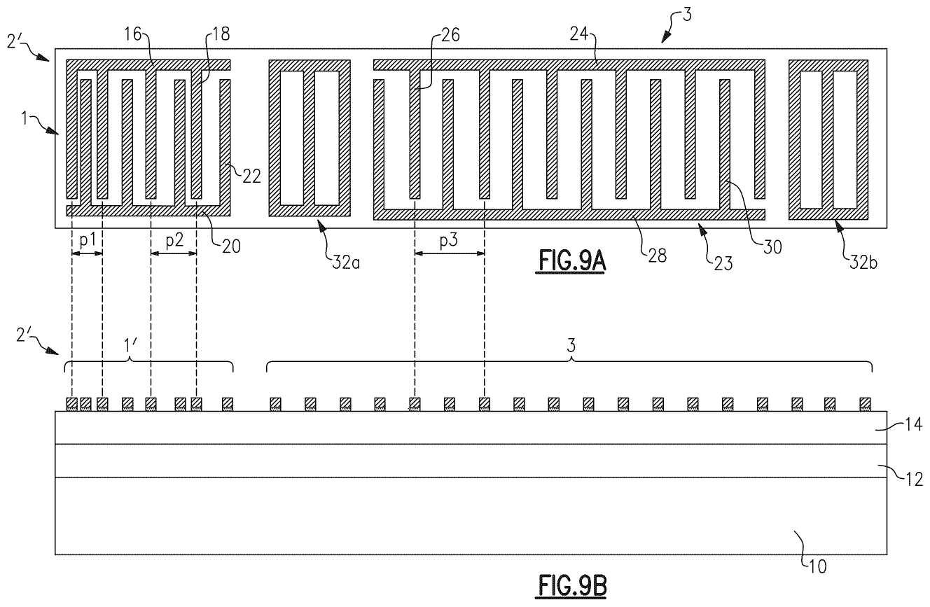

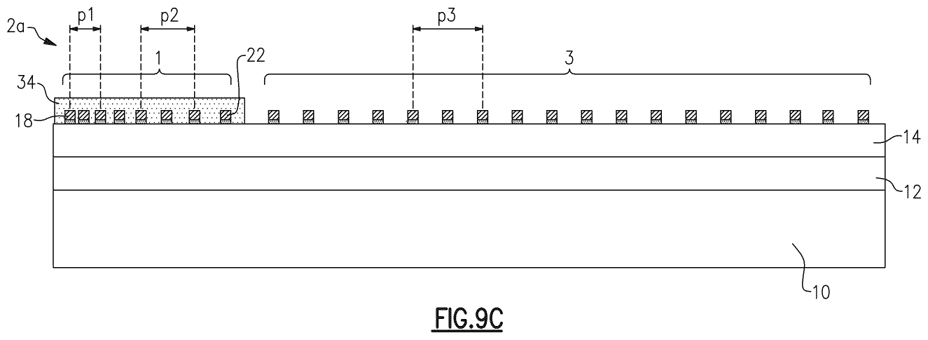

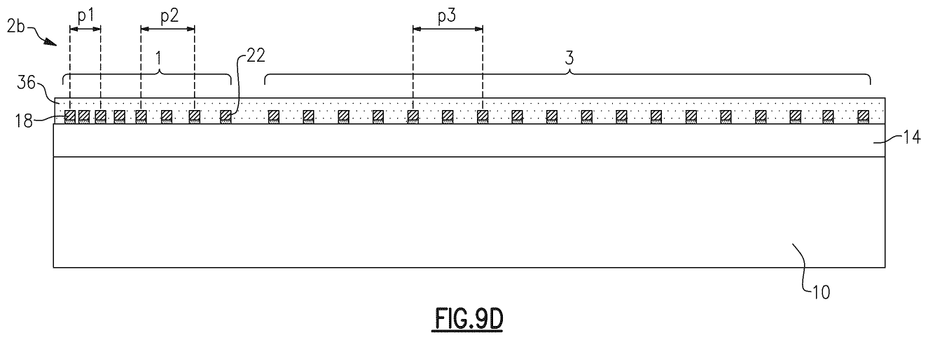

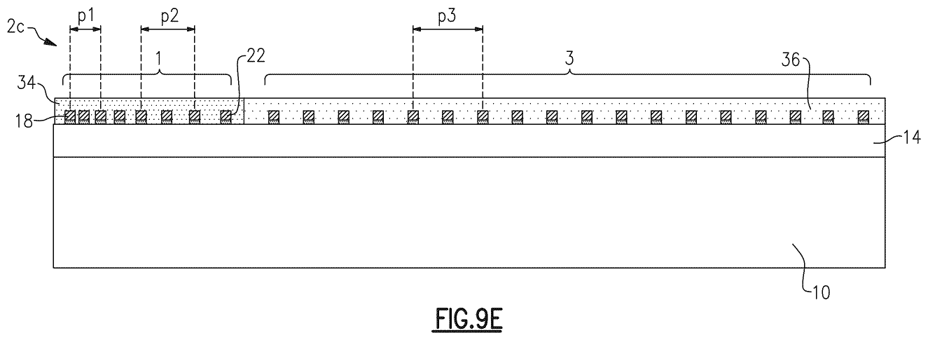

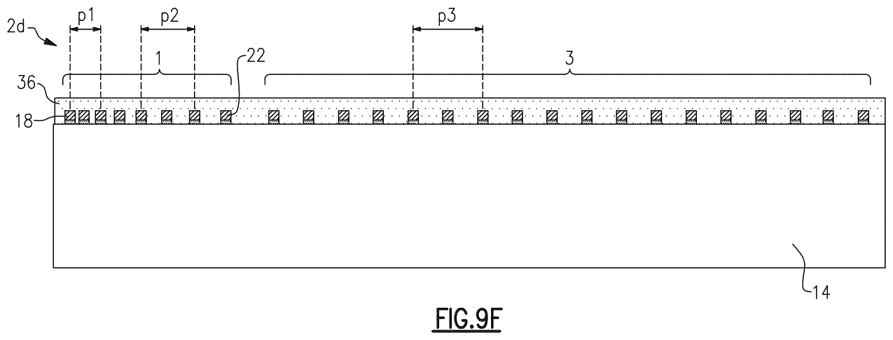

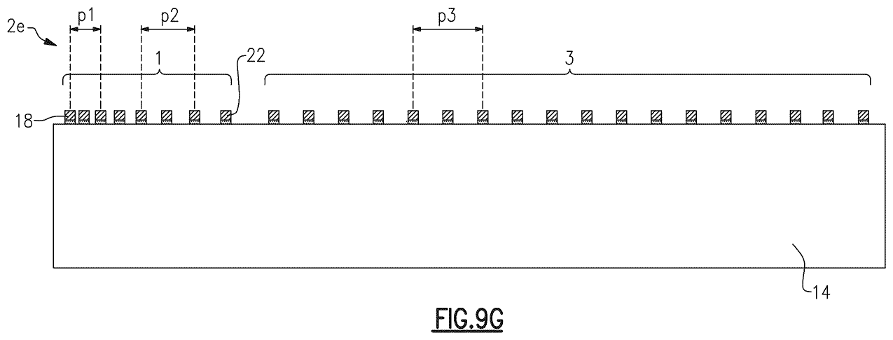

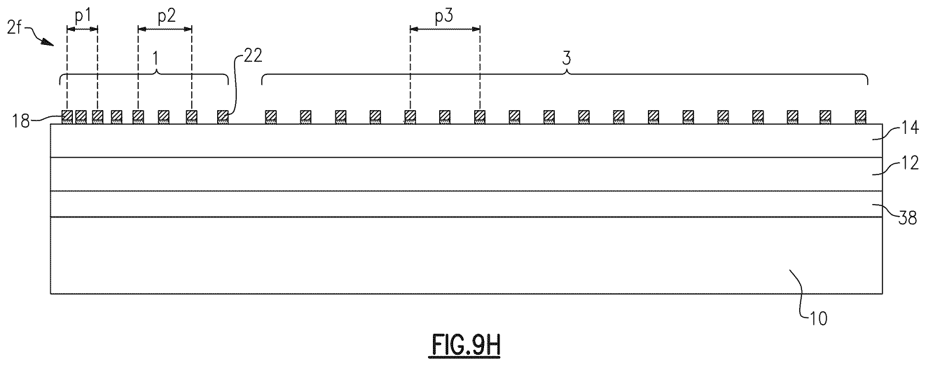

The pitch profile of the capacitor fingers 18, 22 can be modulated in any suitable manner. For example, the capacitor fingers 18, 22 can have a gradation pitch in which the pitches of adjacent capacitor fingers 18, 22 are gradually changed. A gradation pitch can also be referred to as a gradient pitch. As another example, the capacitor fingers 18, 22 can be randomly or pseudo-randomly distributed to have random or pseudo-random pitches (see, for example, FIGS. 9A and 9B) or pseudo-randomly distributed.

In some embodiments, a center of mass of each finger can be shifted to change the pitch. When the center of mass of the capacitor fingers 18, 22 are shifted, the pitch may be changed without changing the pitch between the capacitor fingers 18, 22. In some other embodiments, the dimensions (e.g., a width and/or a height) of each finger can be modified to change the frequency of the wave generated by different pairs of the capacitor fingers 18, 22. Therefore, the pitches and/or dimensions of the capacitor fingers 18, 22 can be selected such that a first pair of adjacent capacitor fingers extending from a bus bar 16, 20 and a second pair of adjacent capacitor fingers extending from the bus bar 16, 20 can have resonances at different frequencies (e.g., a first frequency and a second frequency respectively). The second frequency can be, for example, at least 3%, at least 5%, or at least 8% greater than the first frequency. The second frequency can be, for example, less than 10%, less than 15%, less than 20% greater than the first frequency.

The capacitance of the IDT capacitor 1 can be influenced by the structural features of the capacitor fingers 18, 22. For example, one or more of a length, a width, a height, a pitch, a number of fingers, or a material of an insulator between fingers can influence the capacitance of the IDT capacitor 1. In some embodiments, a number of capacitor fingers 18, 22 can be less than a number of resonator fingers 26, 30.

The IDT electrodes (a bus bar 16, capacitor fingers 18, a bus bar 20, and capacitor fingers 22 of the capacitor 1; and a bus bar 24, resonator fingers 26, a bus bar 28, and resonator fingers 30 of the resonator 3) can include any suitable IDT electrode material. For example, the electrodes can include molybdenum (Mo), aluminum (Al), copper (Cu), Magnesium (Mg), titanium (Ti), tungsten (W), the like, or any suitable combination thereof. The IDT electrodes can have a multilayer structure. For example, the IDT electrodes 23 illustrated in FIGS. 1B and 2B have a multilayer structure that includes a first layer and a second layer. One of the first layer and the second layer can be more electrically conductive than the other, and the other one can be more durable (e.g., resistive to metal fatigue). In some embodiments, the first layer or the second layer can have a higher mass density and/or higher Young's modulus than the other. The interdigital transducer electrodes can be formed with (e.g., formed on or at least partially in) the piezoelectric layer 14. The piezoelectric layer 14 and the electrodes can be provided in any suitable manner. For example, the piezoelectric layer 14 and the electrodes can be provided in sequence. When the electrodes are provided at least partially in the piezoelectric layer 14, the piezoelectric layer 14 can be partially etched and/or provided in a plurality of steps.

In certain applications, a high viscosity material (see, for example, FIG. 9C) can be included over the IDT of the capacitor 1. The high viscosity material together with pitch modulation can reduce or eliminate a spurious response associated with the IDT capacitor 1 in a filter response. The high viscosity material can be a polymer, for example.

The support substrate 10 can have a relatively high acoustic impedance. For example, the support substrate 10 can have a higher impedance than an impedance of the piezoelectric layer 14 and a higher thermal conductivity than a thermal conductivity of the piezoelectric layer 14. The support substrate 10 can be a silicon substrate, for example. The support substrate 10 can be formed of quartz, spinel, borosilicate, or the like. The support substrate 10 can include a dielectric material. For example, the support substrate 10 can include sapphire or aluminum oxide (Al₂O₃). As compared to some other materials, such as silicon, sapphire has lower or no parasitic surface conductance as sapphire is dielectric. The multilayer piezoelectric substrate (MPS) that includes a sapphire support substrate can be referred to as a sapphire MPS.

The intermediate layer 12 can be, for example, a single crystal layer. In some embodiments, the intermediate layer 12 can be a silicon oxide layer (e.g., a silicon dioxide (SiO₂) layer. In some embodiment, the intermediate layer 12 can function as an adhesion layer. In some embodiments, a thickness of the intermediate layer 12 can be the same as, generally similar to, or thinner than the thickness of the piezoelectric layer 14.

The piezoelectric layer 14 can include any suitable piezoelectric layer, such as a lithium based piezoelectric layer. Example lithium based piezoelectric materials include lithium tantalate and lithium niobate. In some embodiments, the piezoelectric layer 14 can be a lithium tantalate (LT) layer. For example, the piezoelectric layer 14 can be an LT layer having a cut angle of 20° (20° Y-cut X-propagation LT), a cut angle of 60° (60° Y-cut X-propagation LT), or a cut angle in a range from 20° to 60°. For example, the piezoelectric layer 10 can be 20°±10° Y-cut LT, 42°±25° Y-cut LT, 42°±20° Y-cut LT, 42°±15° Y-cut LT, 42+10° Y-cut LT, 42°±5° Y-cut LT, 60°±20° Y-cut LT, 60°±15° Y-cut LT, 60°±10° Y-cut LT, or 60°±5° Y-cut LT. Any other suitable piezoelectric material, such as a lithium niobate (LN) layer, can be used as the piezoelectric layer 14. For example, the piezoelectric layer 14 can be an LN layer having a cut angle of about 118° (118° Y-cut X-propagation LN) or more or a cut angle of about 132° (132° Y-cut X-propagation LN) or less. For example, the piezoelectric layer 14 can be 125°±20° Y-cut LN, 125°±15° Y-cut LN, 125°±10° Y-cut LN, or 125°±5° Y-cut LN. A thickness of the piezoelectric layer 14 can be selected based on a wavelength 2 or L of a surface acoustic wave generated by the resonator 3 in certain applications. In some embodiments, the wavelength L can be in a range between, for example, 3 micrometers and 6 micrometers, 3.5 micrometers and 6 micrometers, 3 micrometers and 5.5 micrometers, or 3.5 micrometers and 5.5 micrometers. The piezoelectric layer 14 can be sufficiently thick to avoid significant frequency variation. For example, the thickness of the piezoelectric layer 14 can be in a range of 0.1 L to 0.5 L, 0.1 L to 0.3 L, or 0.1 L to 0.2 L. Selecting the thickness of the piezoelectric layer 14 from these ranges can be significant in avoiding significant frequency variation and providing sufficient temperature coefficient of frequency for the SAW device 2. In some embodiments, the piezoelectric layer 14 can include lithium tantalate (LT) and lithium niobate (LN).

The IDT capacitor 1 and the resonator 3 can be positioned in any suitable manner in the SAW device 2. As illustrated, the IDT capacitor 1 can be positioned along a wave propagation direction (e.g., in a longitudinal direction) of the resonator 3. In some embodiments, the capacitor 1 can be coupled in parallel with the resonator 3. The SAW device 2 can be implemented as part of a filter. The resonator 3 can be a series resonator or a shunt resonator in the filter.

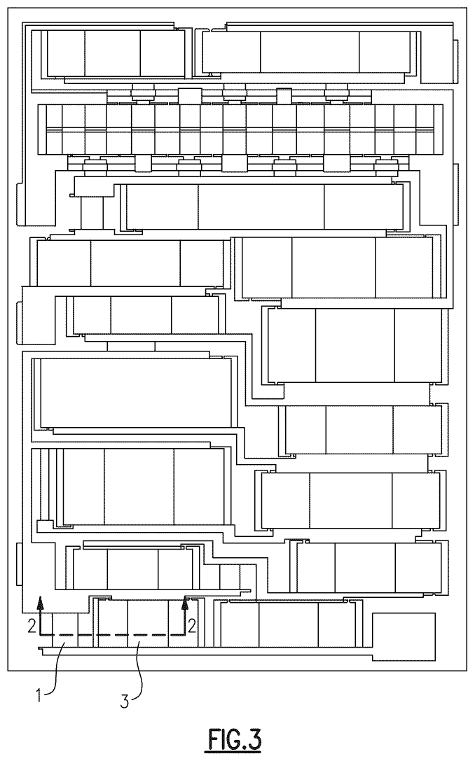

FIG. 3 is a schematic top plan view of an example layout of a filter 4 that includes the SAW device 2. The SAW device 2 in FIGS. 2A and 2B is a cross sectional view along the line 2-2 in FIG. 3. The filter 4 can include a plurality of resonators configured to filter a radio frequency signal. An area of the resonator 3 can be greater than an area of the IDT capacitor 1. A length of the resonator 3 can be greater than a length of the IDT capacitor 1 in a direction of acoustic wave propagation in the resonator 3. In some embodiments, the IDT capacitor 1 can be smaller than any of the plurality of resonators in the filter 4.

The IDT capacitor 1 can be coupled to a resonator (e.g., the resonator 3) in a filter (e.g., the filter 4) to shift (increase or decrease) the coupling factor (kt²) and improve the skirt performance and the insertion loss of the filter. As illustrated in FIG. 3, the IDT capacitor 1 is in parallel with the resonator 3. The IDT capacitors disclosed herein can generate relatively low or no resonance and have a relatively low Q at Fs. Therefore, the IDT capacitors disclosed herein can mitigate or avoid formation of an unwanted frequency response for the filter.

FIG. 4 is a graph showing simulated frequency responses of a filter without an IDT capacitor (Filter 1) and a filter with an IDT capacitor with capacitor fingers having constant pitch between each pair of capacitor fingers (Filter 2). The simulation results indicate that the resonance of the IDT capacitor creates an unwanted response above the filter passband. The unwanted response can be a result of a relatively high Q at the resonant frequency of the IDT capacitor.

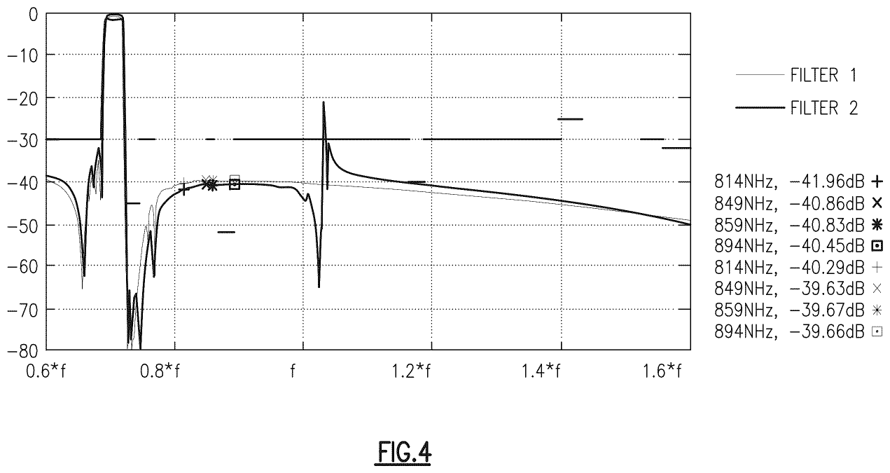

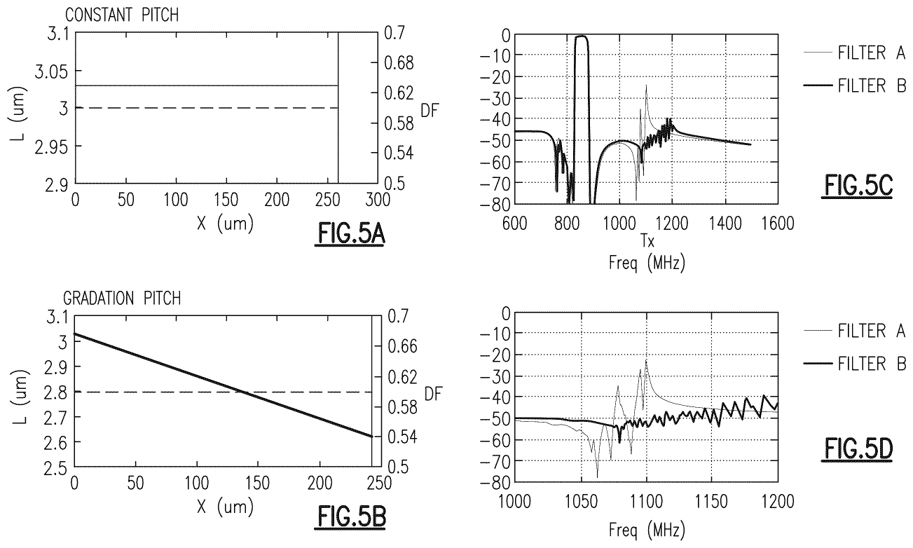

FIG. 5A is a graph showing an example profile of the capacitor fingers of an IDT capacitor with constant pitch. FIG. 5B is a graph showing an example profile of the capacitor fingers of the IDT capacitor according to an embodiment (e.g., the IDT capacitor 1). FIG. 5C is a graph showing simulated frequency responses of the IDT capacitors having the capacitor finger profiles of FIGS. 5A and 5B. FIG. 5D is an enlarged view of a portion of the graph of FIG. 5C. The filter with the IDT capacitor with the capacitor finger profiles of FIG. 5A can be referred to as Filter A, and the filter implementing the IDT capacitor 1 with the capacitor finger profiles of FIG. 5B can be referred to as Filter B. The simulation results indicate that the unwanted response that is present in Filter A is attenuated in Filter B.

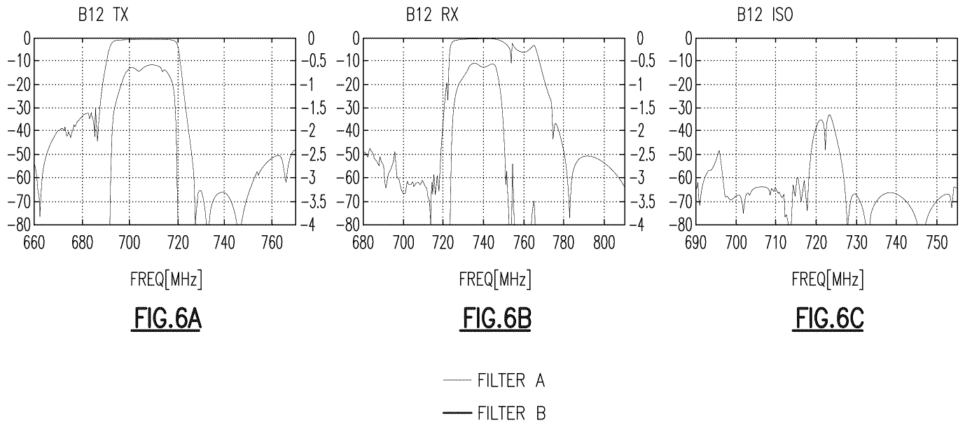

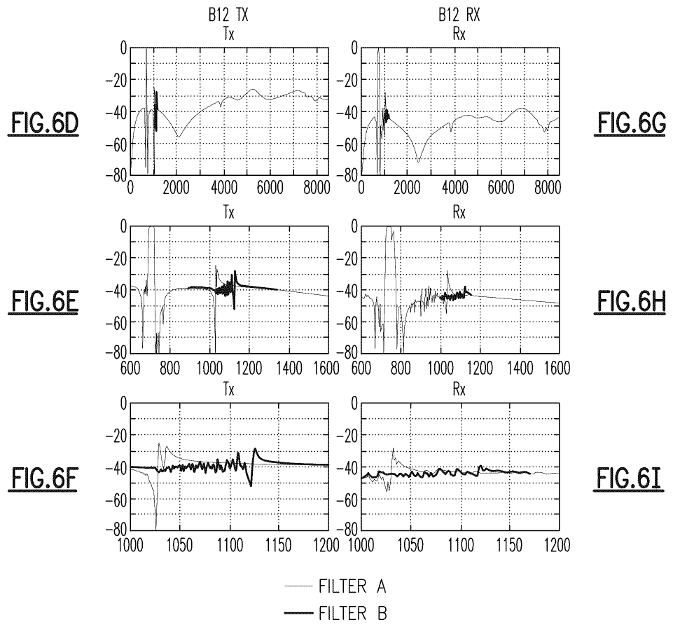

FIGS. 6A-6I show additional simulation results of filters that implement the IDT capacitor having the constant capacitor finger profile and the IDT capacitor 1 having the gradient capacitor finger profile.

FIG. 6A is a graph showing filter responses of Filter A and Filter B as implemented in band 12 transmit filters. FIG. 6B is a graph showing filter responses of Filter A and Filter B as implemented in band 12 receive filters. FIG. 6C is a graph showing filter responses for isolation between a transmit band and a receive band for band 12. FIG. 6A shows the filter responses at a frequency range between 660 megahertz (MHz) and 770 MHz, FIG. 6B shows the filter responses at a frequency range between 680 MHz and 810 MHZ, and FIG. 6C shows the filter responses at a frequency range between 690 MHz and 760 MHz. At these frequency ranges, the filter responses for Filter A and Filter B can generally overlap.

FIGS. 6D-6F are graphs showing filter responses of Filter A and Filter B as implemented in band 12 transmit filters at various frequency ranges. FIGS. 6G-61 are graphs showing filter responses of Filter A and Filter B as implemented in band 12 receive filters at various frequency ranges.

The simulation results indicate that spurious modes are reduced at around resonant frequency using IDT capacitors with gradation pitches. For instances, spurious modes between about 1 gigahertz (GHz) and 1.2 GHz for band 12 DPX were reduced with IDT capacitors with gradation pitches. At the same time, no significant changes with respect to in band performance were observed between Filter A and Filter B.

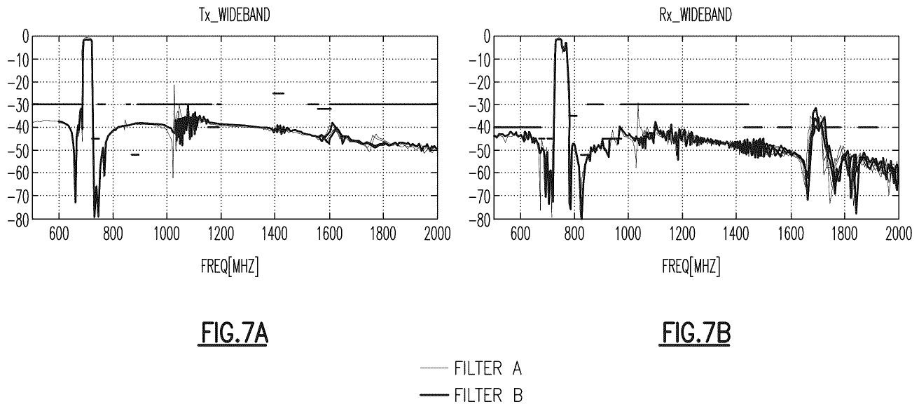

FIG. 7A is a graph showing evaluation board measurement results of Filter A and Filter B as implemented in transmit filters. FIG. 7B is a graph showing evaluation board measurement results of Filter A and Filter B as implemented in transmit filters.

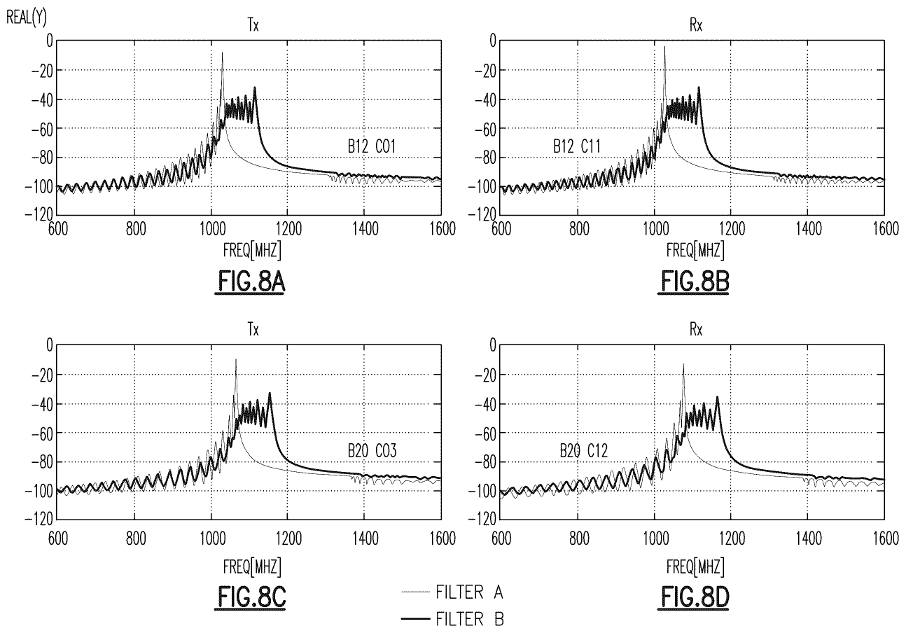

FIG. 8A is a graph showing simulated frequency responses of the IDT capacitor with capacitor fingers having a constant pitch and the IDT capacitor 1 as used in a first channel in a band 12 filter. FIG. 8B is a graph showing simulated frequency responses of the IDT capacitor with capacitor fingers having a constant pitch and the IDT capacitor 1 as used in an eleventh channel in the band 12 filter. FIG. 8C is a graph showing simulated frequency responses of the IDT capacitor with capacitor fingers having a constant pitch and the IDT capacitor 1 as used in a third channel in a band 20 filter. FIG. 8D is a graph showing simulated frequency responses of the IDT capacitor with capacitor fingers having a constant pitch and the IDT capacitor 1 as used in a twelfth channel in the band 20 filter.

The simulation results and measurement results shown in FIGS. 6A-8D indicate significant improvements of resonators and filters that implement the IDT capacitors disclosed herein. One or more IDT capacitors discussed herein can be implemented in a filter. For example, each resonator included in the filter may be coupled to a respective IDT capacitor.

As noted above, the capacitor fingers 18, 22 can be randomly distributed to have random pitches, for example, as shown in FIGS. 9A and 9B. FIG. 9A is a schematic top plan view of a SAW device 2′ that includes the IDT capacitor 1′ and a resonator 3. FIG. 2B is a schematic cross-sectional side view of the SAW device 2′. Unless otherwise noted, the components of the capacitor integrated SAW device 2′ shown in FIGS. 9A and 9B may be structurally and/or functionally the same as or generally similar to like components of other SAW devices disclosed herein.

The pitches of the capacitor fingers 18, 22 can be randomly distributed or have an irregular or non-uniform pattern. The capacitor fingers 18 of the IDT capacitor 1′ have a first pair of adjacent capacitor fingers extending from the bus bar 16 with a first pitch p1 and a second pair of adjacent capacitor fingers extending from the bus bar 16 with a second pitch p2 different from the first pitch p1. The second pitch p2 can be, for example, at least 3%, at least 5%, or at least 8% greater than the first pitch p1. The second pitch p2 can be, for example, less than 10%, less than 15%, less than 20% greater than the first pitch pl. The second pitch p2 can be, for example, at least 0.1 micrometer greater, at least 0.2 micrometers greater, or at least 0.3 micrometers greater than the first pitch p1.

Although FIGS. 2A, 2B, 9A, 9B to 9E, 9G, and 9H illustrate acoustic wave devices with MPS SAW resonators, any suitable principles and advantages disclosed herein can be implemented in association with any other suitable acoustic wave resonators, such as any suitable acoustic wave resonator that includes an IDT electrode. For example, IDT capacitors disclosed herein can be implemented together with one or more of a temperature-compensated SAW resonator, a non-temperature compensated SAW resonator, a boundary acoustic wave resonator, a Lamb wave resonator, or a laterally excited bulk acoustic wave resonator (XBAR). Moreover, in certain embodiments, MPS SAW resonators can include a different number of layers in the MPS and/or include a temperature compensation layer over the IDT electrode.

FIG. 9C is a schematic cross-sectional side view of a SAW device 2a. Unless otherwise noted, the components of the capacitor integrated SAW device 2a shown in FIG. 9C may be structurally and/or functionally the same as or generally similar to like components of other SAW devices disclosed herein. The SAW device 2a can include a high viscosity material 34 over the capacitor fingers 18, 22 of the IDT capacitor 1. The high viscosity material 34 together with pitch modulation can reduce or eliminate a spurious response associated with the IDT capacitor 1 in a filter response. The high viscosity material 34 can have a viscosity that is greater than one or more of the support substrate 10, the intermediate layer 12, or the piezoelectric layer 14. The high viscosity material 34 can be a polymer, for example.

FIG. 9D is a schematic cross-sectional side view of a SAW device 2b. Unless otherwise noted, the components of the capacitor integrated SAW device 2b shown in FIG. 9D may be structurally and/or functionally the same as or generally similar to like components of other SAW devices disclosed herein. The SAW device 2b does not include the intermediate layer 12. In the SAW device 2b, a temperature compensation layer 36 is provided over the IDT capacitor 1 and the resonator 3. The temperature compensation layer 36 can be, for example, a single crystal layer. In some embodiments, the temperature compensation layer 36 can be a silicon oxide layer (e.g., a silicon dioxide (SiO₂)) layer. The temperature compensation 36 layer can bring the temperature coefficient of frequency (TCF) of the SAW device 2b closer to zero. The temperature compensation layer 36 can have a positive TCF.

FIG. 9E is a schematic cross-sectional side view of a SAW device 2c. Unless otherwise noted, the components of the capacitor integrated SAW device 2c shown in FIG. 9E may be structurally and/or functionally the same as or generally similar to like components of other SAW devices disclosed herein. The SAW device 2c is generally similar to the SAW device 2b of FIG. 9D, except that the temperature compensation layer 36 is omitted from the IDT capacitor 1 and the high viscosity material 34 is provided over the capacitor fingers 18, 22 of the IDT capacitor 1.

FIG. 9F is a schematic cross-sectional side view of a SAW device 2d. Unless otherwise noted, the components of the capacitor integrated SAW device 2d shown in FIG. 9F may be structurally and/or functionally the same as or generally similar to like components of other SAW devices disclosed herein. The SAW device 2d is generally similar to the SAW device 2b of FIG. 9D, except that the support substrate 10 is omitted in the SAW device 2d. The SAW device 2d is an example of a temperature compensated surface acoustic wave (TC-SAW) device.

FIG. 9G is a schematic cross-sectional side view of a SAW device 2e. Unless otherwise noted, the components of the capacitor integrated SAW device 2e shown in FIG. 9G may be structurally and/or functionally the same as or generally similar to like components of other SAW devices disclosed herein. The SAW device 2e is generally similar to the SAW device 2d of FIG. 9F, except that the temperature compensation layer 36 is omitted in the SAW device 2e. The SAW resonator 3 of the SAW device 2e can be referred to as a non-temperature compensated SAW resonator.

FIG. 9H is a schematic cross-sectional side view of a SAW device 2f. Unless otherwise noted, the components of the capacitor integrated SAW device 2f shown in FIG. 9H may be structurally and/or functionally the same as or generally similar to like components of other SAW devices disclosed herein. The SAW device 2f is generally similar to the SAW device 2 of FIG. 9B, except that the SAW device 2f also includes an additional layer 38. In some embodiments, the additional layer 38 can be a trap rich layer. In some embodiments, the trap rich layer can mitigate the parasitic surface conductivity of the support substrate 10. The trap rich layer can be formed in a number of ways, for example, by forming the surface of the support substrate 10 with amorphous or polycrystalline silicon, by forming the surface of the support substrate 10 with porous silicon, or by introducing defects into the surface of the support substrate 10 via ion implantation, ion milling, or other methods. In some embodiments, the trap rich layer can improve the electrical characteristics of the SAW device 2f by increasing the depth and sharpness on the anti-resonance peak.

An acoustic wave device (e.g., a SAW device) including any suitable combination of features disclosed herein can be included in a filter arranged to filter a radio frequency signal in a fifth generation (5G) New Radio (NR) operating band within Frequency Range 1 (FR1). A filter arranged to filter a radio frequency signal in a 5G NR operating band can include one or more packaged MPS-SAW devices disclosed herein. FR1 can be from 410MHz to 7.125 GHz, for example, as specified in a current 5G NR specification. One or more acoustic wave devices in accordance with any suitable principles and advantages disclosed herein can be included in a filter arranged to filter a radio frequency signal in a 4G LTE operating band. One or more acoustic wave devices in accordance with any suitable principles and advantages disclosed herein can be included in a filter having a passband that includes a 4G LTE operating band and a 5G NR operating band. One or more acoustic wave devices in accordance with any suitable principles and advantages disclosed herein can be included in a filter with any other suitable passband or stop band, such as a filter for a Wi-Fi operating band.

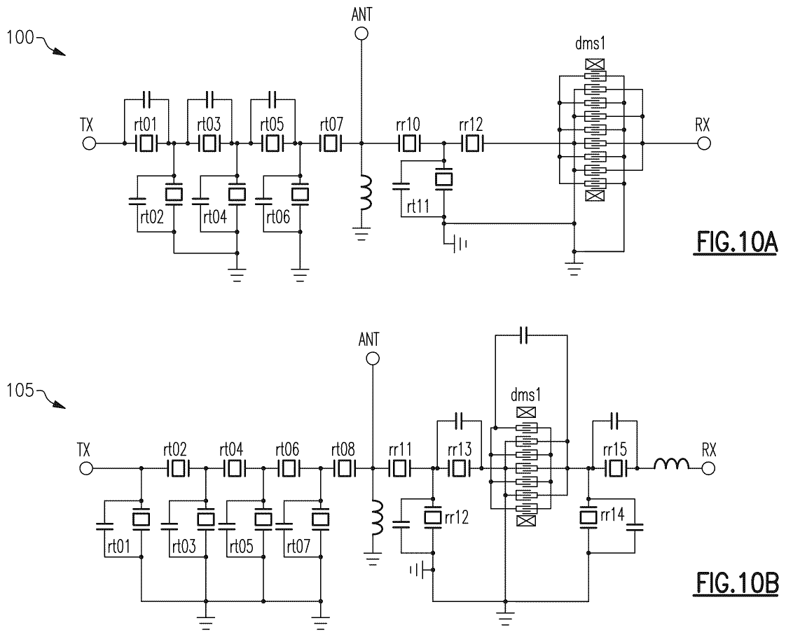

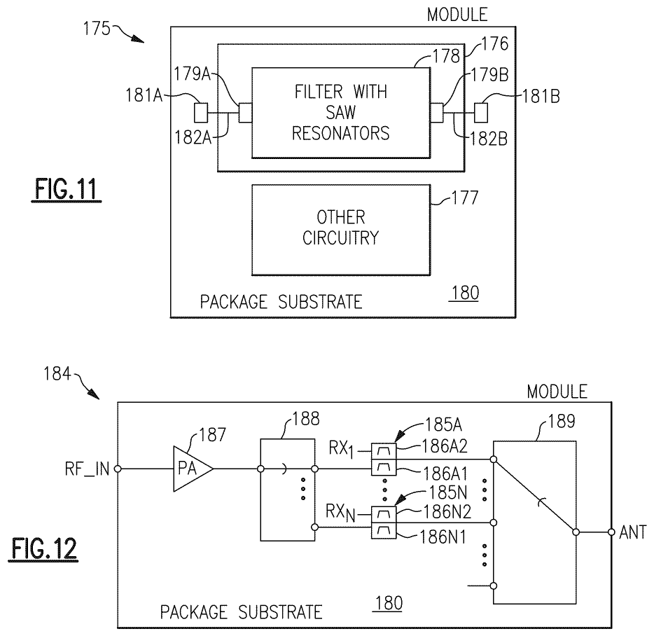

FIG. 10A is a schematic diagram of an example multiplexer 100 that includes surface acoustic wave devices according to an embodiment. The multiplexer 100 can be a duplexer. The multiplexer 100 includes a transmit filter and a receive filter. For example, the transmit filter can be a band pass filter. The illustrated transmit filter in the multiplexer 100 is arranged to filter a radio frequency signal received at a transmit port TX and provide a filtered output signal to an antenna port ANT. The illustrated receive filter in the multiplexer 100 is arranged to filter a radio frequency signal received at the antenna port ANT and provide a filtered output to a receive port RX. The transmit filter includes resonators rt01 to rt07. The resonators rt01, rt03, rt05, and rt07 are series resonators and rt02, rt04, tr06 are shunt resonators. The receive filter includes resonators rr10, rr11, rr12, and a multi-mode SAW filter (e.g., a double mode SAW filter dms1). The resonators rr10, rr12 are series resonators and the resonator rr1 is a shunt resonator.

The multiplexer 100 also includes capacitors coupled in parallel with the resonators rt01, rt02, rt03, rt04, rt05, rt06, and rr11. The capacitors can include one or more IDT capacitors in accordance with any suitable principles and advantages disclosed herein. The transmit filter and the receive filter of the multiplexer 100 can have a relatively small gap between passbands. Using IDT capacitors disclosed herein can reduce the impact of one or more capacitors from the transmit filter on the passband of the receive filter and/or reduce the impact of one or more capacitors of the receive filter on the transmit filter.

FIG. 10B is a schematic diagram of another multiplexer 105 that includes surface acoustic wave devices according to an embodiment. The multiplexer 105 can be a duplexer. The multiplexer 105 includes a transmit filter and a receive filter. For example, the transmit filter can be a band pass filter. The illustrated transmit filter in the multiplexer 105 is arranged to filter a radio frequency signal received at a transmit port TX and provide a filtered output signal to an antenna port ANT. The illustrated receive filter in the multiplexer 105 is arranged to filter a radio frequency signal received at the antenna port ANT and provide a filtered output to a receive port RX. The transmit filter includes resonators rt01 to rt08. The resonators rt02, rt04, rt06, and rt08 are series resonators and rt01, rt03, rt05, and rt07 are shunt resonators. The receive filter includes resonators rr11 to rr15, and a multi-mode SAW filter (e.g., a double mode SAW filter dms1). The resonators rr1, rr13, and rr15 are series resonators and the resonators rr12, rr14 are shunt resonators.

The multiplexer 105 also includes capacitors coupled in parallel with the resonators rt01, rt03, rt05, rt07, rt12, rt13, rr14, and rr15 and with the DMS filter dms1. The capacitors can include one or more IDT capacitors in accordance with any suitable principles and advantages disclosed herein.

Any suitable filter topology can include an IDT capacitor in accordance with any suitable principles and advantages disclosed herein. Example filter topologies include ladder topology, a lattice topology, a hybrid ladder and lattice topology, a multi-mode SAW filter, a multi-mode SAW filter combined with one or more other SAW resonators, and the like.

FIG. 11 is a schematic diagram of a radio frequency module 175 that includes a surface acoustic wave component 176. The illustrated radio frequency module 175 includes the SAW component 176 and other circuitry 177. The SAW component 176 can include one or more SAW resonators with any suitable combination of features of the SAW resonators disclosed herein. The SAW component 176 can include a SAW die that includes SAW resonators.

The SAW component 176 shown in FIG. 11 includes a filter 178 and terminals 179A and 179B. The filter 178 includes SAW resonators. One or more of the SAW resonators can be implemented in accordance with any suitable principles and advantages of any surface acoustic wave device disclosed herein. The terminals 179A and 178B can serve, for example, as an input contact and an output contact. The SAW component 176 and the other circuitry 177 are on a common packaging substrate 180 in FIG. 11. The packaging substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

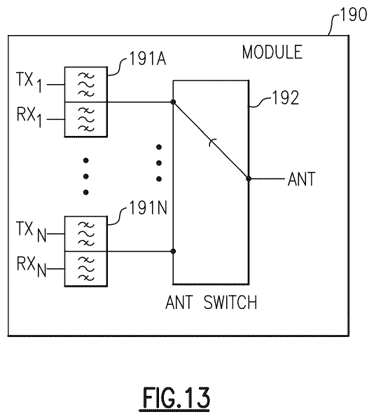

FIG. 12 is a schematic diagram of a radio frequency module 184 that includes a surface acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate 180 can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW resonators in accordance with any suitable principles and advantages disclosed herein. Similarly, one or more of the receive filters 186A2 to 186N2 can include one or more SAW resonators in accordance with any suitable principles and advantages disclosed herein. Although FIG. 12 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

FIG. 13 is a schematic block diagram of a module 190 that includes duplexers 191A to 191N and an antenna switch 192. One or more filters of the duplexers 191A to 191N can include any suitable number of surface acoustic wave resonators in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

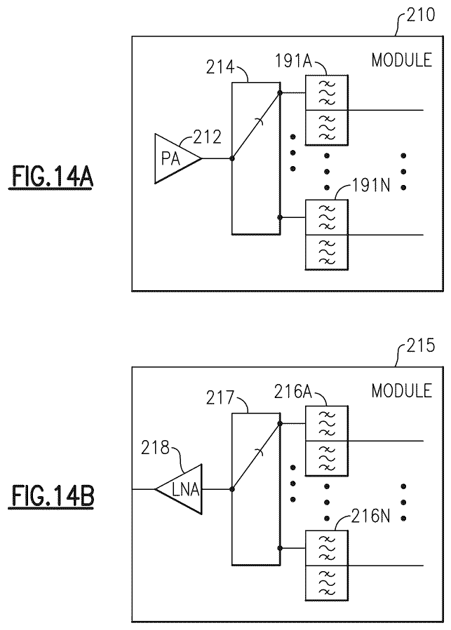

FIG. 14A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of surface acoustic wave resonators in accordance with any suitable principles and advantages discussed herein. Any suitable number of duplexers 191A to 191N can be implemented.

FIG. 14B is a schematic block diagram of a module 215 that includes filters 216A to 216N, a radio frequency switch 217, and a low noise amplifier 218 according to an embodiment. One or more filters of the filters 216A to 216N can include any suitable number of acoustic wave resonators in accordance with any suitable principles and advantages disclosed herein. Any suitable number of filters 216A to 216N can be implemented. The illustrated filters 216A to 216N are receive filters. In some embodiments, one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments, a plurality of low noise amplifiers can be implemented. The module 215 can include diversity receive features in certain applications.

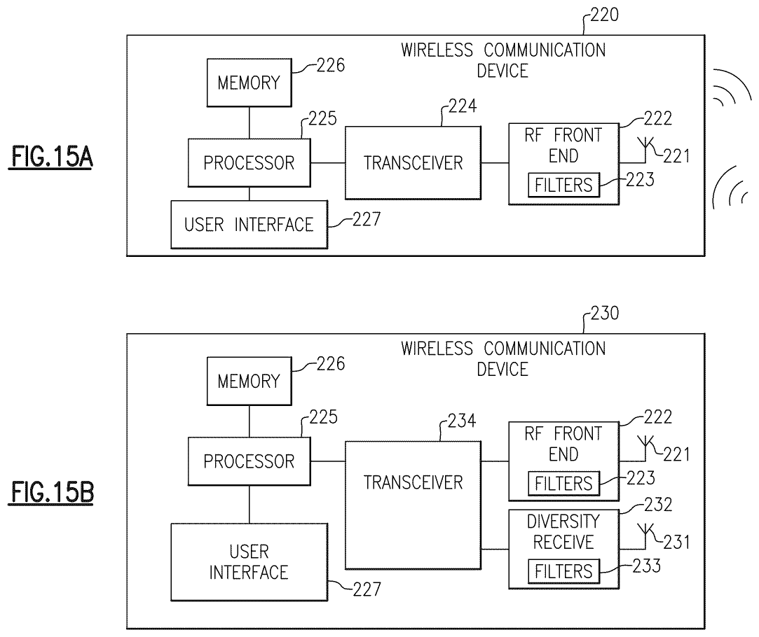

FIG. 15A is a schematic diagram of a wireless communication device 220 that includes filters 223 in a radio frequency front end 222 according to an embodiment. The filters 223 can include one or more SAW resonators in accordance with any suitable principles and advantages discussed herein. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards. The filters 223 can include SAW resonators of a SAW component that includes any suitable combination of features discussed with reference to any embodiments discussed above.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 15B is a schematic diagram of a wireless communication device 230 that includes filters 223 in a radio frequency front end 222 and a second filter 233 in a diversity receive module 232. The wireless communication device 230 is like the wireless communication device 220 of FIG. 15A, except that the wireless communication device 230 also includes diversity receive features. As illustrated in FIG. 15B, the wireless communication device 230 includes a diversity antenna 231, a diversity receive module 232 configured to process signals received by the diversity antenna 231 and including filters 233, and a transceiver 234 in communication with both the radio frequency front end 222 and the diversity receive module 232. The filters 233 can include one or more SAW resonators that include any suitable combination of features discussed with reference to any embodiments discussed above.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. An acoustic wave device comprising:
a piezoelectric layer having a first region and a second region;
an interdigital transducer capacitor in the first region, the interdigital transducer capacitor including capacitor fingers including a first pair of adjacent capacitor fingers extending from a bus bar with a first pitch and a second pair of adjacent capacitor fingers extending from the bus bar with a second pitch different from the first pitch; and
an acoustic wave resonator in the second region, the acoustic wave resonator including an interdigital transducer electrode in communication with the piezoelectric layer, the interdigital transducer electrode including resonator fingers having a pair of adjacent resonator fingers with a third pitch, the third pitch being different from both the first pitch and the second pitch.

2. The acoustic wave device of claim 1 wherein the third pitch is greater than both the first pitch and the second pitch.

3. The acoustic wave device of claim 1 wherein a number of the resonator fingers is greater than a number of the capacitor fingers.

4. The acoustic wave device of claim 1 wherein the second pitch is at least 3% greater than the first pitch.

5. The acoustic wave device of claim 4 where in the second pitch is less than 15% greater than the first pitch.

6. The acoustic wave device of claim 1 wherein an area of the acoustic wave resonator is greater than an area of the interdigital transducer capacitor.

7. The acoustic wave device of claim 1 wherein the acoustic wave resonator is longer than the interdigital transducer capacitor along a wave propagation direction of the acoustic wave resonator.

8. The acoustic wave device of claim 1 wherein the interdigital transducer capacitor is free from an acoustic reflector.

9. The acoustic wave device of claim 1 wherein pitches of the capacitor fingers have a gradient.

10. The acoustic wave device of claim 1 wherein pitches of the capacitor fingers are random or pseudo-random.

11. The acoustic wave device of claim 1 wherein the interdigital transducer capacitor generates substantially no aggregate resonance.

12. The acoustic wave device of claim 1 wherein the interdigital transducer capacitor is positioned along a wave propagation direction of the acoustic wave resonator.

13. The acoustic wave device of claim 1 further comprising a high viscosity material, the capacitor fingers positioned between the high viscosity material and the piezoelectric layer, and the high viscosity material having a higher viscosity than the piezoelectric layer.

14. The acoustic wave device of claim 1 further comprising a support substrate, the piezoelectric layer positioned between the support substrate and the interdigital transducer electrode.

15. The acoustic wave device of claim 1 further comprising a support substrate and an intermediate layer positioned between the support substrate and the piezoelectric layer.

16. The acoustic wave device of claim 1 wherein the interdigital transducer capacitor is in parallel with the acoustic wave resonator.

17. An interdigital transducer capacitor comprising:
a piezoelectric layer; and
an interdigital transducer including a bus bar and capacitor fingers on the piezoelectric layer, the capacitor fingers including a first pair of adjacent capacitor fingers extending from the bus bar with a first pitch and a second pair of adjacent capacitor fingers extending from the bus bar with a second pitch different from the first pitch.

18. The interdigital transducer capacitor of claim 17 wherein pitches of the capacitor fingers are modulated such that the interdigital transducer capacitor generates substantially no aggregate resonance.

19. An acoustic wave filter for filtering a radio frequency signal, the acoustic wave filter comprising:
an interdigital transducer capacitor including capacitor fingers on a piezoelectric layer, the capacitor fingers including a first pair of adjacent capacitor fingers extending from a bus bar with a first pitch and a second pair of adjacent capacitor fingers extending from the bus bar with a second pitch different from the first pitch;
an acoustic wave resonator including an interdigital transducer electrode in communication with the piezoelectric layer, the interdigital transducer electrode including resonator fingers having a pair of adjacent resonator fingers with a third pitch, the third pitch being different from both the first pitch and the second pitch, and the interdigital transducer capacitor being in parallel with the acoustic wave resonator; and
a plurality of additional acoustic wave resonators, the acoustic wave resonator and the plurality of additional acoustic wave resonators configured to filter the radio frequency signal.

20. The acoustic wave filter of claim 19 further comprising a second interdigital transducer capacitor in parallel with a second acoustic wave resonator of the plurality of additional acoustic wave resonators.
